(19) United States
(12) Patent Application Publication
(10) Pub. No.: US 2025/0293026 A1
(43) Pub. Date: Sep. 18, 2025

(54) HIGH-POWER CARBON HARDMASK DEPOSITION AND CHARGE DISSIPATION

(71) Applicant: Applied Materials, Inc., Santa Clara, CA (US)

(72) Inventors: Abdul Aziz Khaja, San Jose, CA (US); Ruiyun Huang, Santa Clara, CA (US)

(73) Assignee: Applied Materials, Inc., Santa Clara, CA (US)

(21) Appl. No.: 18/606,604

(22) Filed: Mar. 15, 2024

(51) Int. Cl. H01L 21/02; H01J 37/32; H01L 21/033

(52) U.S. Cl. CPC H01L 21/02642; H01J 37/32174; H01J 37/3244; H01L 21/0332; H01L 21/0337

(57) ABSTRACT

Carbon-containing hard masks are generally formed using plasmas that are maintained using RF power below about 3000 W to prevent charge to build up on the faceplate resulting in current arcs. Described herein are techniques for forming a carbon-containing hardmask using RF power above 3000 W. This high-power process may be performed such that the processing region is kept free of current arcs. A carbon-based layer may be formed on the showerhead or faceplate to distribute charge and prevent the current arcs from charge buildup. A charge drain may also be included that collects charge from the surface of the substrate during the deposition process and provides a conductive pathway from the processing region to reduce the potential for current arcs.

### TECHNICAL FIELD

This disclosure generally describes techniques for forming a carbon hardmask during semiconductor manufacturing processes. More specifically, this disclosure describes a high-power technique for forming carbon hardmasks with charge dissipation to reduce arcing.

### BACKGROUND

Integrated circuits are made possible by processes which produce intricately patterned material layers on substrate surfaces. Producing patterned material on a substrate requires controlled methods for forming and removing material. Deposition processes may form material that attaches to many components of the system. Carbon hardmask deposition processes play a crucial role in semiconductor manufacturing, particularly in advanced integrated circuit fabrication. However, the current state of these processes poses significant challenges that impact the overall efficiency and quality of the deposition process. One major issue is the generation of current arcs that higher power levels, leading to image to the chamber and the substrate. Moreover, the current arcs in high-power RF carbon hardmask deposition processes often exhibit unwanted side effects such as overheating and localized damage to the underlying layers. The excessive heat generated during the arcing events can compromise the structural integrity of the semiconductor material, affecting device reliability and performance. Additionally, the issue of arc-induced contamination poses a significant hurdle in the current state of high-power RF carbon hardmask deposition processes. Uncontrolled arcing events can lead to the release of particles and by-products that contaminate the semiconductor surface. This contamination adversely affects the yield and reliability of the fabricated devices.

Thus, there is a need for improved systems and methods that can be used to produce high quality devices and structures. These and other needs are addressed by the present technology.

### SUMMARY

In some embodiments, a semiconductor processing method may include flowing a carbon-containing precursor into a processing region of a semiconductor processing chamber; forming a plasma of a carbon-containing precursor within the processing region of the semiconductor processing chamber; applying a radio-frequency (RF) power to the plasma that is greater than 3000 W; and performing a deposition process on a semiconductor substrate disposed within the processing region of the semiconductor processing chamber to form a carbon hardmask film on the semiconductor substrate, where the processing region may be free of current arcs between the semiconductor substrate and the semiconductor processing chamber.

In some embodiments, a semiconductor processing chamber may include a gas distributor assembly configured to provide a carbon-based precursor to the semiconductor processing chamber, where the gas distributor assembly comprises a faceplate. The chamber may also include a substrate support configured to support a semiconductor substrate during a deposition process to form a carbon hardmask on the semiconductor substrate, where the substrate support and the faceplate may at least partially define a processing region in the semiconductor processing chamber. The chamber may further include and a radio-frequency (RF) power supply programmed to provide power to a plasma in the processing region during the deposition process, where the RF power may be greater than 3000 W. The chamber may also include a charge drain that collects charge from a surface of the semiconductor substrate during the deposition process and provides a conductive pathway from the processing region for the charge such that the processing region is free of current arcs between the semiconductor substrate and the faceplate during the deposition process.

In some embodiments, a semiconductor processing method may include flowing a carbon-containing precursor into a processing region of a semiconductor processing chamber; forming a plasma of a carbon-containing precursor within the processing region of the semiconductor processing chamber; applying a first radio-frequency (RF) power to the plasma that is less than 3000 W and forming a carbon-based layer on a faceplate of the semiconductor processing chamber; applying a second RF power to the plasma that is greater than 3000 W; and performing a deposition process on a semiconductor substrate disposed within the processing region of the semiconductor processing chamber to form a carbon hardmask film on the semiconductor substrate. The carbon-based layer may provide a conductive surface on the faceplate to distribute charge and prevent current arcs between the semiconductor substrate and the faceplate.

In any embodiments, any and all of the following features may be implemented in any combination and without limitation. The carbon-containing precursor may be flowed through a faceplate into the processing region of the semiconductor processing chamber, and the faceplate may include a conductive metal that is uncoated and exposed to the processing region. The carbon-containing precursor may be flowed through a faceplate into the processing region of the semiconductor processing chamber, and the faceplate may be coated with a conductive layer that allows charge to be evenly distributed on the conductive layer. The conductive layer may be a carbon-based layer that is formed on the faceplate using a power that is less than 3000 W. The carbon-containing precursor may be flowed through a faceplate into the processing region of the semiconductor processing chamber, and the faceplate may be coated with a silicon-based seasoning layer that is between about 1.5 μm and about 0.5 μm thick. The silicon-based seasoning layer may be applied directly to the faceplate without a coating comprising an oxide between the silicon-based seasoning layer and the faceplate. Charge that collects on a surface of the semiconductor substrate during the deposition process may be drained through a charge drain that provides a conductive pathway from the processing region. The charge drain may dissipate charge from the surface of the semiconductor substrate during the deposition process at a rate that may be greater than or equal to a rate at which charge forms on the surface of the semiconductor substrate. The charge drain may include a positive electrode in the substrate support, where the positive electrode may be coupled to a positive output of a bipolar electrostatic chuck (ESC). The bipolar ESC may include a floating power supply with a positive terminal coupled to the positive electrode and a negative terminal that may be coupled to a negative electrode in the substrate support. The substrate support may include a carbon-based layer that allows charge that collects on the substrate support to dissipate through the charge drain. The faceplate may include a conductive surface that dissipates charge that builds up on the faceplate during the deposition process. Prior to applying the first RF power to the plasma, an RF power may be applied to the plasma that is less than 1000 W to form an initial layer for the carbon-based layer on a surface of the faceplate. The RF power that is less than 1000 W may be applied for between about 20 seconds and about 60 seconds. The first RF power may be applied for between about 20 seconds and about 60 seconds. The first RF power may be between about 2300 W and about 2500 W. The carbon-based layer may be between about 100 nm and about 250 nm thick.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

FIG. 1 illustrates a cross-sectional view of an exemplary processing chamber, according to some embodiments.

FIG. 2 illustrates a flowchart of a method for high-power deposition of carbon hardmasks, according to some embodiments.

FIG. 3 illustrates a faceplate during a high-power carbon-hardmask process, according to some embodiments.

FIG. 4 illustrates a faceplate that is uncoated with an oxide coating, according to some embodiments.

FIG. 5A illustrates a faceplate with a seasoning layer, according to some embodiments.

FIG. 5B illustrates a faceplate with a seasoning layer and a carbon-based layer, according to some embodiments.

FIG. 6 illustrates an example configuration of a semiconductor processing chamber with a charge drain in the substrate support, according to some embodiments.

### DETAILED DESCRIPTION

Presently, carbon-containing hard masks are generally formed using plasmas that are maintained using RF power below about 3000 W. Although power levels may produce better hardmask results, a number of technical problems exist when applying high-power RF signals to the plasma during the deposition process. For example, high-power RF generally causes more charge to build up on the faceplate and/or the semiconductor substrate. When this charge builds up, arcing can occur when an electrical discharge takes place between the semiconductor substrate and the faceplate. Other current arcs resulting from charge buildup may also occur between the faceplate and other portions of the processing chamber. Additionally, higher-temperatures (e.g., above about 600° C.) further exacerbate this problem by increasing the likelihood of current arcs. These arcs damage the faceplate and damage the semiconductor substrate. This leads to lower yield when manufacturing substrates, and leads to permanent faceplate damage requiring frequent replacement.

The embodiments described herein solve these and other technical problems by allowing for a carbon-containing hardmask to be formed using RF power above 3000 W. This high-power process is performed such that the processing region is kept free of current arcs. For example, a carbon-based layer may be formed on the showerhead or faceplate to distribute charge and prevent the current arcs from charge buildup. A charge drain may also be included that collects charge from the surface of the substrate during the deposition process and provides a conductive pathway from the processing region to reduce the potential for current arcs.

Although the remaining disclosure will routinely identify specific deposition processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible chamber that may include components and may be operated according to embodiments of the present technology before additional variations and adjustments to this system according to embodiments of the present technology are described.

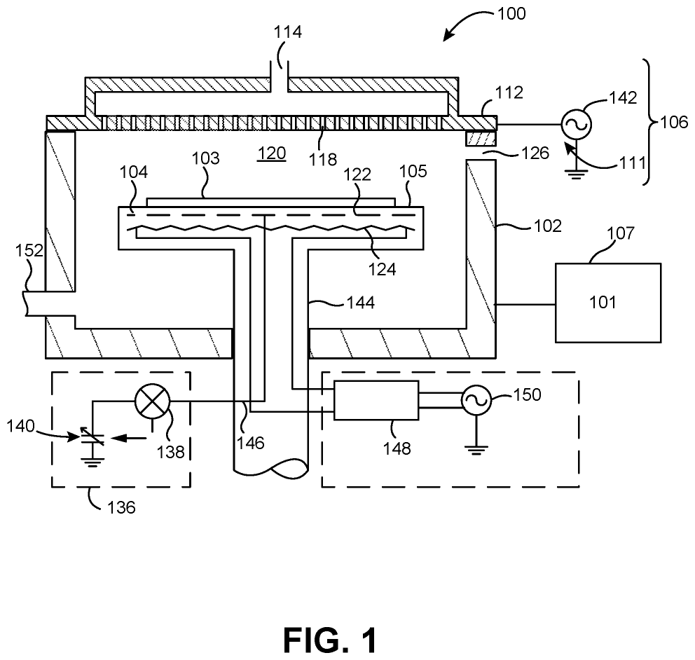

FIG. 1 shows a cross-sectional view of an exemplary processing chamber 100, according to some embodiments. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

Presently, carbon-containing hard mask are generally formed using plasmas that are maintained using RF power below about 3000 W. Although power levels may produce better hardmask results, a number of technical problems exist when applying high-power RF signals to the plasma during the deposition process. For example, high-power RF generally causes more charge to build up on the faceplate and/or the semiconductor substrate. When this charge builds up, arcing can occur when an electrical discharge takes place between the semiconductor substrate and the faceplate. Other current arcs resulting from charge buildup may also occur between the faceplate and other portions of the processing chamber. Additionally, higher-temperatures (e.g., above about 600° C.) further exacerbate this problem by increasing the likelihood of current arcs. These arcs damage the faceplate and damage the semiconductor substrate. This leads to lower yield when manufacturing substrates, and leads to permanent faceplate damage requiring frequent replacement.

The embodiments described herein solve these and other technical problems. Specifically, the techniques described below allow for very high-power RF (e.g., greater than about 3000 W) to be applied to the plasma while effectively preventing arcing from occurring. This allows for higher-quality carbon hardmasks without reducing the substrate yield and/or the resulting damage to the faceplate or other portions of the processing chamber. A number of different techniques described below may be applied individually or in any combination in order to reduce or prevent arcing when using high-power plasmas to form carbon hardmasks.

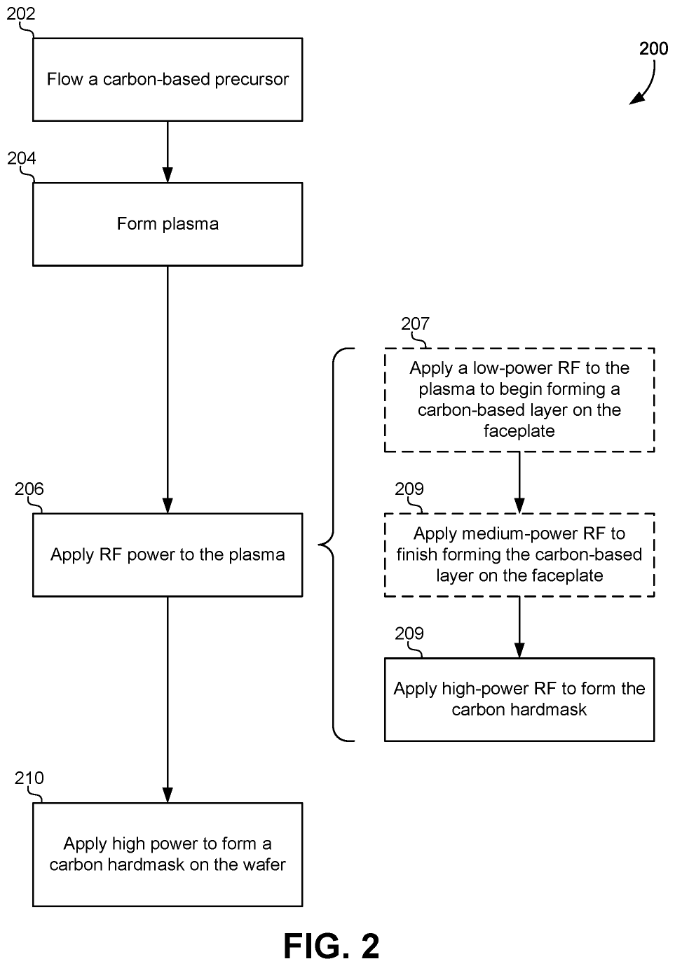

FIG. 2 illustrates a flowchart of a method 200 for high-power deposition of carbon hardmasks, according to some embodiments. The method may be performed in a variety of processing chambers, including processing system 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

In some embodiments, method 200 may be performed in a processing chamber that includes a faceplate 202, such as gas distributor 112 discussed above. The term “faceplate” is used herein by way of example and is not meant to be limiting. Therefore, the techniques described below for the faceplate may readily be applied to other portions of the lid or gas distributor 212 assembly without limitation. The faceplate 202 may be manufactured from a conductive metal, such as aluminum or some other material used for components in plasma processing chambers. The surface of the faceplate 202 may therefore be very conductive, having a near-zero resistance. This allows the surface of the faceplate 202 to readily dissipate charge that builds up on the surface of the faceplate to ground.

The faceplate may be installed in a processing chamber, when used, and method 200 may be performed on a substrate positioned within the processing chamber, such as on substrate support 104. Although the remaining disclosure may discuss development of a carbon-containing film, it is to be understood that the present technology may encompass a deposition process, a removal process, or some other semiconductor processes that may be performed on the substrate within the processing region of the chamber. These techniques may also involve processing that may utilize an oxygen-containing plasma. In one exemplary deposition process encompassed by the present technology, a carbon-containing hardmask, such as a carbon film or a carbon-containing film, may be deposited on the substrate.

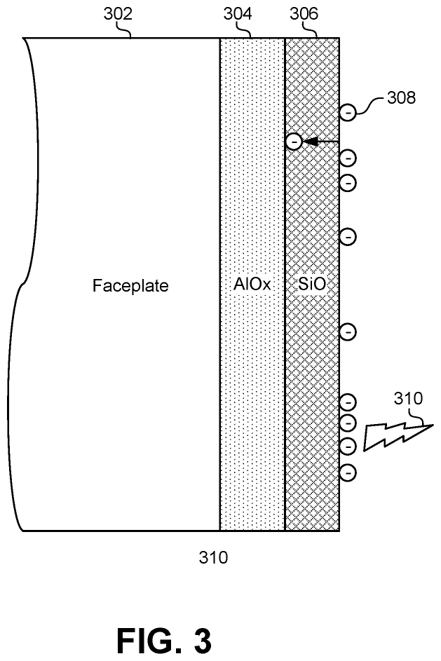

FIG. 3 illustrates a faceplate 302 during a high-power carbon-hardmask process, according to some embodiments. The hardmask formation process may be performed in a processing chamber that includes a faceplate 302, such as gas distributor 112 discussed above. The term “faceplate” is used herein by way of example and is not meant to be limiting. Therefore, the techniques described below for the faceplate may readily be applied to other portions of the lid or gas distributor 312 assembly without limitation. The faceplate 302 may be manufactured from a conductive metal, such as aluminum or some other material used for components in plasma processing chambers. The surface of the faceplate 302 may therefore be very conductive, having a near-zero resistance. This allows the surface of the faceplate 302 to readily dissipate charge that builds up on the surface of the faceplate to ground.

Generally, most faceplates include an oxide coating 304 that is applied to the surface of the faceplate. For example, the oxide coating 304 may be a metal oxide coating formed on the faceplate. The oxide coating 304 may include any number of metals that may facilitate reduction in erosion or corrosion during plasma processing. For example, the oxide used in the oxide coating 304 may be developed from aluminum, silicon, yttrium, zirconium, hafnium, or any other metal, transition metal, post-transition metal, metalloid, or combination of metals. The oxide coating 304 may range from between about 100 nm to about 1000 nm in thickness. For example, the oxide coating 304 may be between about 100 nm and about 200 nm, between about 200 nm and about 300 nm, between about 300 nm and about 400 nm, between about 400 nm and about 500 nm, between about 500 nm and about 600 nm, between about 600 nm and about 700 nm, between about 700 nm and about 800 nm, between about 800 nm and about 900 nm, and/or between about 900 nm and about 1000 nm. The thickness of the oxide coating 304 may also be any combination of these ranges (e.g., between about 300 nm and about 600 nm). The thickness of the oxide coating 304 may also be any specific value within these ranges (e.g., about 450 nm).

Some embodiments may also form a seasoning layer 306 over the oxide coating 304. For example, before applying precursors for forming a carbon hardmasks a silicon-based seasoning layer 306 may be formed over the oxide layer 304. The seasoning layer 306 may include a number of different materials, such as silicon oxide as illustrated in FIG. 3. The seasoning layer 306 may range from between about 100 nm to about 3000 nm in thickness. For example, the seasoning layer 306 may be between about 100 nm and about 300 nm, between about 300 nm and about 500 nm, between about 500 nm and about 700 nm, between about 700 nm and about 900 nm, between about 900 nm and about 1100 nm, between about 1100 nm and about 1300 nm, between about 1300 nm and about 1500 nm, between about 1500 nm and about 1700 nm, between about 1700 nm and about 1900 nm, between about 1900 nm and about 2100 nm, between about 2100 nm and about 2300 nm, between about 2300 nm and about 2500 nm, between about 2500 nm and about 2700 nm, and/or between about 2700 nm and about 3000 nm. The thickness of the seasoning layer 306 may also be any combination of these ranges (e.g., between about 300 nm and about 700 nm). The thickness of the seasoning layer 306 may also be any specific value within these ranges (e.g., about 500 nm).

The seasoning layer 306 may be formed by first flowing a silicon-based precursor into the processing region of the semiconductor processing chamber. The silicon-based precursor may include silane, tetraethyl orthosilicate (TEOS), and other similar materials. Some embodiments may also form a seasoning layer 306 that includes a plurality of layers. For example, bilayers of silicon oxide and silicon nitride may be formed as the seasoning layer 306.

A faceplate 302 with an oxide coating 304 and a seasoning layer 306 may produce arc-free results at low-power plasma processes when forming carbon hardmasks. However, when the power is increased above about 3000 W and/or the temperature is increased above about 600° C., the buildup of charge 308 on the surface also increase accordingly. As the rate of charge buildup increases, the charge 308 cannot dissipate fast enough on the surface of the seasoning layer 306. For example, dipoles may form at the junction between the two dielectric layers formed by the oxide coating 304 and the seasoning layer 306. This may cause the charge 308 to build up instead of tunnel from the surface of the seasoning layer 306 to the surface of the faceplate 302 where the charge 308 may then be easily dissipated and grounded through the faceplate 302. When the buildup of the charge 308 exceeds a threshold, an arc 310 of current may discharge from the surface of the seasoning layer 306. This arc 310 may discharge into the semiconductor substrate, thereby damaging the faceplate 302 and/or the semiconductor substrate.

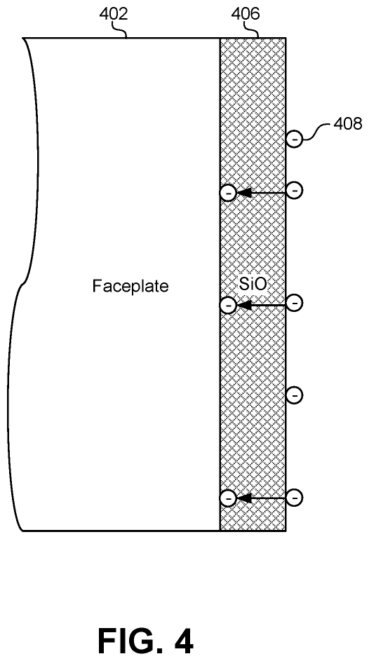

FIG. 4 illustrates a faceplate 402 that is uncoated with an oxide coating, according to some embodiments. A number of techniques are described herein to reduce the charge buildup on the faceplate. For example, some embodiments may use a high-power RF (e.g., above about 3000 W) for the plasma when forming the carbon hardmask. When the high-power RF is applied, the faceplate 402 may be substantially free of any other coating or layer. For example, the faceplate 402 may be substantially uncoated by an oxide coating 404 and/or a seasoning layer 406. The aluminum (or other conductive metal) of the faceplate 402 may be directly exposed to the processing region. This may allow any charge that builds up on the surface of the faceplate 402 to be readily discharged through the grounded faceplate.

In the example of FIG. 4, some embodiments may eliminate the oxide coating 404 while still using the seasoning layer 406. If the seasoning layer 406 is thin enough, the charge 408 can pass through the single dielectric layer of the seasoning layer 406 fast enough to be dissipated by the faceplate 402. For example, at power levels greater than about 3000 W, a seasoning layer 406 that is less than about 2 μm (about 2000 nm) may be thin enough to dissipate charge through the seasoning layer 406. The thickness of the seasoning layer 406 may be between about 2 μm and about 1.5 μm, between about 1.5 μm and about 1.0 μm, between about 1.0 μm and about 0.5 μm, and/or less than about 0.5 μm. The thickness of the seasoning layer 406 may also be any combination of these ranges (e.g., between about 1.5 μm and about 0.5 μm). The thickness of the seasoning layer 406 may also be any specific value within these ranges (e.g., about 0.5 μm).

Turning back to FIG. 2, the method may include flowing a carbon-containing precursor into a processing region of a semiconductor processing chamber (202). The method may further include forming a plasma of a carbon-containing precursor within the processing region of the semiconductor processing chamber (204). The plasma may be formed in the processing region in order to form a carbon hardmask on the semiconductor substrate.

As described above, the quality of the carbon hardmask may be improved by applying very high-power RF to the plasma during the deposition process. In order to prevent current arcs from occurring between the semiconductor substrate and portions of the semiconductor processing chamber (e.g., the faceplate), certain conditions may be imposed on the faceplate. For example, for RF power between about 3000 W and about 4300 W, and uncoated faceplate may be used. The bare-metal of the faceplate may allow the more rapid charge buildup to dissipate fast enough that current arcs may be prevented. Alternatively, some embodiments may use a faceplate that includes a seasoning layer without an oxide coating as described above in FIG. 4. If the seasoning layer is then enough (e.g., less than about 0.5 μm or one of the other ranges described above) then the charge may dissipate through the seasoning layer to the faceplate fast enough that current arcs may be prevented.

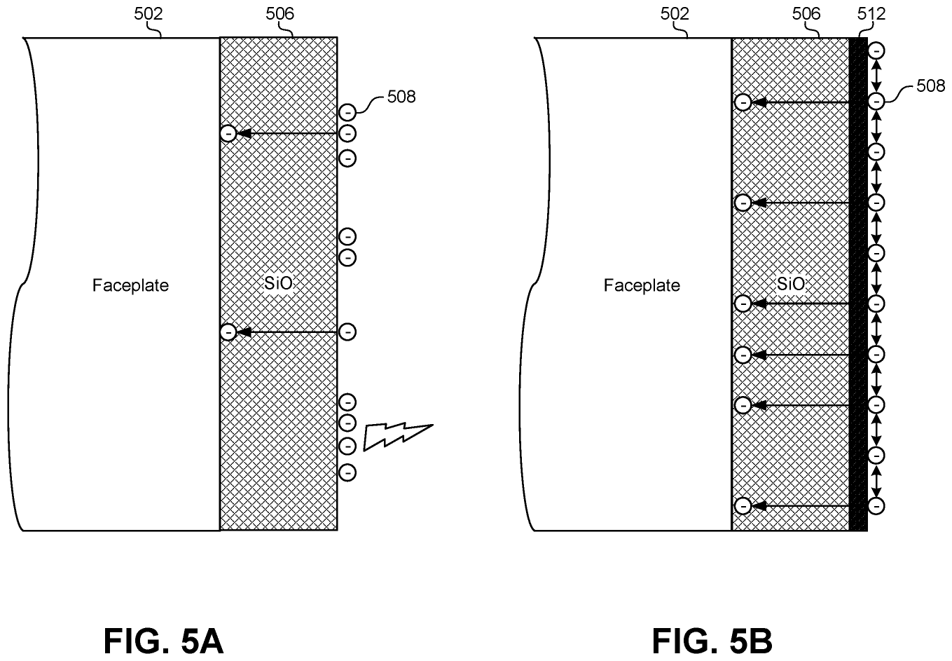

However, when using processes that apply more than about 4300 W of RF power, the charge may buildup so quickly on the seasoning layer that the charge may not be distributed fast enough to prevent current arcs from occurring. FIG. 5A illustrates a faceplate 502 with a seasoning layer 506, according to some embodiments. At higher RF power levels, the charge 508 may buildup abruptly and/or so quickly on the surface of the seasoning layer 506 that the charge 508 is unable to evenly distribute itself on the surface of the seasoning layer 506. This leads to a smaller amount of the charge being able to tunnel through the seasoning layer 506 to be dissipated at the grounded faceplate 502.

FIG. 5B illustrates a faceplate 502 with a seasoning layer 506 and a carbon-based layer 512, according to some embodiments. The carbon-based layer 512 may be relatively thin, but may still provide a conductive surface that allows the charge 508 to evenly distribute itself across the surface of the carbon-based layer 512. This allows the charge 508 to be more readily transferred to the faceplate 502 where the charge 508 can be dissipated to ground. The carbon-based layer 512 may also prevent damage to the seasoning layer 506 that may occur at high-power RF levels.

In some embodiments, the carbon-based layer 512 may be formed as part of the plasma process performed in the semiconductor processing chamber. For example, the method 200 may additionally include applying an RF power to the plasma (206). Although not shown explicitly in FIG. 2, RF power may initially be applied in order to strike or form the plasma, and the RF power may continue to be applied during the deposition process in order to maintain the plasma while the carbon hardmask is formed. Generally, after an initial stage where the carbon-based layer 512 may be formed on the faceplate 502, the RF power may be characterized by being greater than about 3000 W.

Turning back to FIG. 2, when forming the carbon-based layer 512 as part of the plasma process, the method 200 may optionally include applying a relatively low-power RF power to the plasma to form the carbon-based layer 512 on the faceplate 502 (207). For example, the low-power RF may be between about 400 W and about 450 W, between about 450 W and about 500 W, between about 500 W and about 550 W, between about 550 W and about 600 W, between about 600 W and about 650 W, between about 650 W and about 700 W, between about 700 W and about 750 W, between about 750 W and about 800 W, between about 800 W and about 850 W, between about 850 W and about 900 W, between about 900 W and about 950 W, between about 950 W and about 1000 W. The power range of the relatively low-power RF may also be any combination of these ranges (e.g., between about 600 W and about 800 W). The RF power may also be any specific value within these ranges (e.g., about 700 W).

The low-power RF may be applied for between about 5 s and about 10 s, between about 10 s and about 20 s, between about 20 s and about 30 s, between about 30 s and about 40 s, between about 40 s and about 50 s, between about 50 s and about 60 s, between about 60 s and about 70 s, between about 70 s and about 80 s, between about 80 s and about 90 s, and/or between about 90 s and about 100 s. The time during which the relatively low-power RF is applied may also be any combination of these ranges (e.g., between about 20 s and about 40 s). The time during which the relatively low-power RF is applied may also be any specific value within these ranges (e.g., about 30 seconds).

The relatively low-power RF may be applied to begin forming the carbon-based layer 512. These initial layers of the carbon-based layer 512 may also serve to prevent peeling on the seasoning layer 506. For example, at relatively high RF power levels (e.g., greater than about 4300 W), a high-stress film on the seasoning layer 506 may cause peeling, which may consequently result in arcing. This initial layer of the carbon-based layer 512 allows subsequent layers to be formed at higher power levels. Specifically, a carbon-carbon bond between layers may exhibit better adhesion than carbon-SiOx layers because the surface energy of the carbon-carbon layers are similar.

After applying the low-power RF, the method 200 may optionally increase the RF power to apply a medium-power RF to finish forming the carbon-based layer on the faceplate (209). For example, the medium-power RF may be between about 1800 W and about 1900 W, between about 1900 W and about 2000 W, between about 2000 W and about 2100 W, between about 2100 W and about 2200 W, between about 2200 W and about 2300 W, between about 2300 W and about 2400 W, between about 2400 W and about 2500 W, between about 2500 W and about 2600 W, between about 2600 W and about 2700 W, between about 2700 W and about 2800 W, between about 2800 W and about 2900 W, and/or between about 2900 W and about 3000 W. The power range of the medium-power RF may also be any combination of these ranges (e.g., between about 2300 W and about 2500 W). The RF power may also be any specific value within these ranges (e.g., about 2400 W).

The medium-power RF may be applied for between about 5 s and about 10 s, between about 10 s and about 20 s, between about 20 s and about 30 s, between about 30 s and about 40 s, between about 40 s and about 50 s, between about 50 s and about 60 s, between about 60 s and about 70 s, between about 70 s and about 80 s, between about 80 s and about 90 s, and/or between about 90 s and about 100 s. The time during which the medium-power RF is applied may also be any combination of these ranges (e.g., between about 20 s and about 40 s). The time during which the medium-power RF is applied may also be any specific value within these ranges (e.g., about 30 seconds).

In some embodiments, the application of the relatively low-power RF (207) may be considered optional and may be omitted. Instead, the medium-power RF may be directly applied at the beginning of the operation without first applying the low-power RF. Additionally, some RF power ranges may not require the carbon-based layer as described above, and may instead rely on a bare (uncoated) faceplate or a faceplate with a relatively thin seasoning layer in the ranges described above, particularly for power ranges between about 3000 W and about 4300 W. Application of the carbon-based layer may be used for any power range, but may be particularly useful for power ranges that are above about 4300 W.

Although specific time ranges were provided above for applying the low-power RF and/or the medium-power RF to form the carbon-based layer, other embodiments may be characterized by a target thickness of the carbon-based layer. For example, the medium-power RF may be applied until a target thickness of the carbon-based layer is reached. The target thickness of the carbon-based layer may be between about 50 nm and about 100 nm, between about 100 nm and about 150 nm, between about 150 nm and about 200 nm, between about 200 nm and about 250 nm, between about 250 nm and about 300 nm, between about 300 nm and about 350 nm, between about 350 nm and about 400 nm, between about 400 nm and about 450 nm, and/or between about 450 nm and about 500 nm (0.5 μm). The thickness of the carbon-based layer may also be any combination of these ranges (e.g., between about 100 nm and about 250 nm). The thickness of the carbon-based layer may also be any specific value within these ranges (e.g., about 150 nm).

The method 200 may further include performing a deposition process on a semiconductor substrate disposed within the processing region of the semiconductor processing chamber to form a carbon hardmask film on the semiconductor substrate (210). The RF power when forming the bulk of the carbon hardmask may be greater than about 3000 W. For example, the RF power may between about 3000 W and about 3500 Watts, between about 3500 W and about 4000 W, between about 4000 W and about 4500 Watts, between about 4500 W and about 5000 W, between about 5000 W and about 5500 Watts, between about 5500 W and about 6000 W, between about 6000 W and about 6500 Watts, and/or between about 6500 W and about 7000 W. The RF power may also be any combination of these ranges (e.g., between about 3500 W and about 4500 W). The RF power may also be any specific value within these ranges (e.g., about 3800 W, about 4300 W, etc.).

As described above, the ability to apply high-power RF when forming the carbon hardmask may at least partially depend on the rate of charge dissipation on the faceplate. For example, the deposition process may be characterized by a rate of charge dissipation at the faceplate that is greater than a rate of charge collection of the faceplate. In other words, the ability of the faceplate to dissipate charge to ground may be greater than the rate at which charge builds up on the faceplate due to the RF power applied to the plasma. As the RF power increases, the faster the charge may be dissipated at the faceplate to avoid current arcs. Specific techniques for increasing the rate of dissipation at the faceplate may include the uncoated faceplate, the faceplate coated with a thin seasoning layer, and/or the faceplate coated with a conductive coating (e.g., a carbon-based layer) as described above to dissipate charge on the faceplate. These techniques may be used in any combination and without limitation.

Alternatively or additionally, the deposition process for the carbon hardmask may be characterized by a lack of current arcs within the semiconductor processing chamber. For example, the various techniques presented in this disclosure may be used singly or may be combined until the processing region is free of current arcs between the substrate and the semiconductor processing chamber. Current arcs may also be eliminated between the substrate and sidewalls of the processing chamber or between the faceplate and other portions of the processing chamber. Since configurations of deposition chambers may vary, these various techniques may be applied selectively and to varying degrees for each specific processing chamber until the current arcs are eliminated.

While facilitating the dissipation of charge on the faceplate may greatly reduce current arcs, these techniques may also be combined with techniques for dissipating charge that may build up on the substrate itself and/or the substrate support. By dissipating charge on the faceplate and the substrate and/or substrate support, the probability of current arcs occurring may be further minimized, particularly when using high-power RF.

It should be appreciated that the specific steps illustrated in FIG. 2 provide particular methods of for high-power deposition of carbon hardmasks according to various embodiments. Other sequences of steps may also be performed according to alternative embodiments. For example, alternative embodiments may perform the steps outlined above in a different order. Moreover, the individual steps illustrated in FIG. 2 may include multiple sub-steps that may be performed in various sequences as appropriate to the individual step. Furthermore, additional steps may be added or removed depending on the particular applications. Many variations, modifications, and alternatives also fall within the scope of this disclosure.

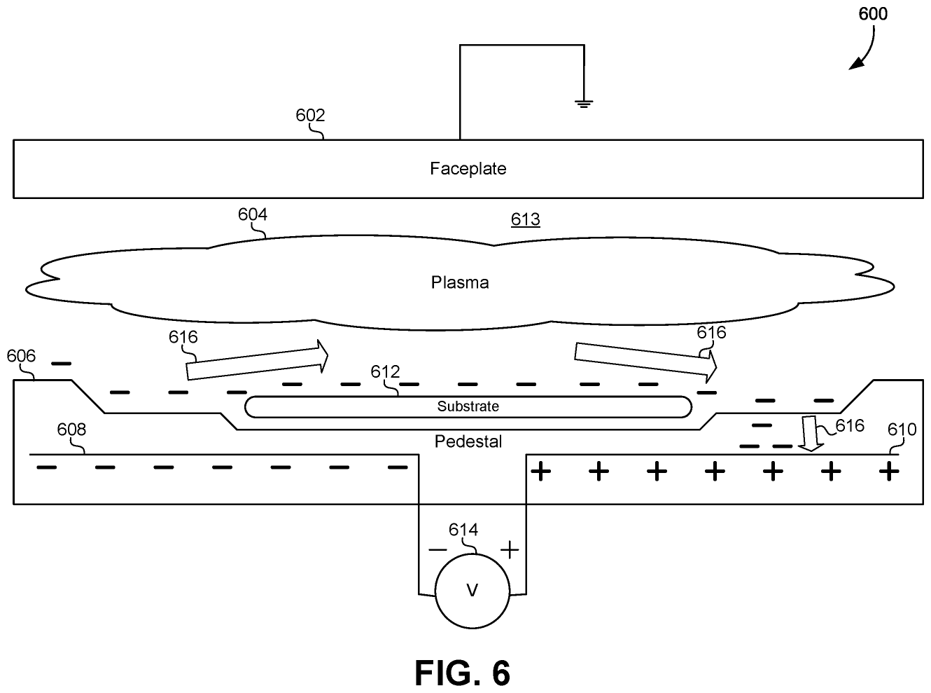

FIG. 6 illustrates an example configuration of a semiconductor processing chamber with a charge drain in the substrate support, according to some embodiments. Typically, carbon hardmasks have been deposited using a monopolar electrostatic chuck (ESC). A monopolar ESC provides a DC voltage to an electrode in the semiconductor substrate. When charge accumulates on the electrode in the support, an opposing charge accumulates on the semiconductor substrate. These opposing charges result in an attracting force that holds the semiconductor substrate to the substrate support. However, the charge buildup on the semiconductor substrate increases the likelihood of current arcs between the substrate and the semiconductor processing chamber.

The embodiments described herein also solve the problem of charge buildup on the semiconductor substrate by providing an optional charge drain that collects charge from the surface of the semiconductor substrate during the deposition process. The charge drain provides a conductive pathway out of the processing region for the charge. By removing charge from the semiconductor substrate, the processing region may be further likely to remain free of current arcs between the substrate and, for example, the faceplate during the deposition process. The charge drain may include any charge pathway from the semiconductor substrate and/or substrate support that allows charge to drain out of the processing region.

FIG. 6 illustrates one example of a charge drain that may be used to prevent current arcs. Instead of using a monopolar ESC, a bipolar ESC may be used with a floating power supply. For example, a semiconductor processing chamber 600 may include a substrate support 606 that includes a first electrode 608 and a second electrode 610. These electrodes may be coupled to opposing outputs of a power supply 614. The power supply may be a direct-current (DC) or RF power supply having negative and positive outputs. The positive and negative outputs may be coupled to the first electrode 608 and the second electrode 610, respectively. The first electrode 608 and the second electrode 610 may include wire meshes or other conductive materials in the substrate support 606. The first electrode 608 and the second electrode may be shaped as hemispheres, concentric rings, or other geometric configurations beneath a semiconductor substrate 612.

The substrate support 606 may be configured to support the semiconductor substrate 612 during the deposition process when forming a carbon hardmask on the semiconductor substrate 612. A processing region 613 may be at least partially defined by a faceplate 602 and the substrate support 606. For example, the processing region 613 may be defined by the space above the substrate support 606 and below the faceplate 602. Although not shown explicitly, the processing region 613 may be further defined by a housing or vertical walls of the semiconductor processing chamber 600. The processing region 613 may also be defined as a volume within the semiconductor processing chamber 600 that is occupied by a plasma 604 that is formed between the faceplate 602 and substrate support 606 during the deposition process.

Other bipolar ESC systems may use separate power supplies for the first electrode 608 and the second electrode 610. For example, the first electrode 608 may be electrically coupled to a negative output of a first power supply with the positive output coupled to ground. The second electrode 610 may be electrically coupled to a positive output of a second power supply with the negative output coupled to ground. In contrast, these embodiments may use a floating power supply 614 where the negative output is coupled to the first electrode 608 and the positive output is coupled to the second electrode 610. By floating the power supply 614, the system can ensure that the opposing voltages applied to the two electrodes are equal and opposite.

In addition to improving the uniformity of the chucking voltage between the two electrodes, floating the power supply 614 in the bipolar ESC may create a charge drain 616 that allows charge buildup on the semiconductor substrate 612 to exit the processing region 613. For example, during the deposition process, charge that builds up on the substrate support 606 and/or the semiconductor substrate 612 may follow the conductive path 616 to the second electrode 610 (e.g., the positive electrode). Therefore, instead of building up on the semiconductor substrate 612, the charge may follow the conductive path 616 away from the semiconductor substrate 612. This greatly reduces the charge density on the semiconductor substrate 612 and thereby reduces arcing in the processing region 613. Because of the closed-loop nature of the floating power supply 614, the net current flow across the semiconductor substrate 612 may be approximately zero. As charge is induced by the first electrode 608, an equal amount of charge may be dissipated through the second electrode 610. This allows the charge on the semiconductor substrate 612 to be dissipated at a rate that is approximately greater than or equal to the rate at which the charge accumulates on the semiconductor substrate 612.

The conductive path 616 may be in particularly useful on insulating substrates (e.g., substrates with alternating oxide-nitride layers) where charge buildup is more likely. Additionally, as the carbon hardmask is formed on the substrate 612, the carbon layer may conduct the charge more readily across the surface of the semiconductor substrate 612. A carbon layer may also form on the substrate support 606 during the deposition process, which may further facilitate the conduction of charge to the region of the charge drain 616. For example, a carbon layer on the surface of the substrate support 606 may allow the conductive path 616 of the charge drain to further remove charge buildup from the substrate support 606.

As used herein, the terms “about” or “approximately” or “substantially” may be interpreted as being within a range that would be expected by one having ordinary skill in the art in light of the specification. For example, these terms may represent values within 10% of a stated value.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor processing method comprising:
flowing a carbon-containing precursor into a processing region of a semiconductor processing chamber;
forming a plasma of a carbon-containing precursor within the processing region of the semiconductor processing chamber;
applying a radio-frequency (RF) power to the plasma that is greater than 3000 W; and
performing a deposition process on a semiconductor substrate disposed within the processing region of the semiconductor processing chamber to form a carbon hardmask film on the semiconductor substrate, wherein the processing region is free of current arcs between the semiconductor substrate and the semiconductor processing chamber.

2. The semiconductor processing method of claim 1, wherein the carbon-containing precursor is flowed through a faceplate into the processing region of the semiconductor processing chamber, and the faceplate comprises a conductive metal that is uncoated and exposed to the processing region.

3. The semiconductor processing method of claim 1, wherein the carbon-containing precursor is flowed through a faceplate into the processing region of the semiconductor processing chamber, and the faceplate is coated with a conductive layer that allows charge to be evenly distributed on the conductive layer.

4. The semiconductor processing method of claim 3, wherein the conductive layer comprises a carbon-based layer that is formed on the faceplate using a power that is less than 3000 W.

5. The semiconductor processing method of claim 1, wherein the carbon-containing precursor are flowed through a faceplate into the processing region of the semiconductor processing chamber, and wherein the faceplate is coated with a silicon-based seasoning layer that is between about 1.5 μm and about 0.5 μm thick.

6. The semiconductor processing method of claim 5, wherein the silicon-based seasoning layer is applied directly to the faceplate without a coating comprising an oxide between the silicon-based seasoning layer and the faceplate.

7. The semiconductor processing method of claim 5, further comprising draining charge that collects on a surface of the semiconductor substrate during the deposition process through a charge drain that provides a conductive pathway from the processing region.

8. A semiconductor processing chamber comprising:
a gas distributor assembly configured to provide a carbon-based precursor to the semiconductor processing chamber, wherein the gas distributor assembly comprises a faceplate;
a substrate support configured to support a semiconductor substrate during a deposition process to form a carbon hardmask on the semiconductor substrate, wherein the substrate support and the faceplate at least partially define a processing region in the semiconductor processing chamber; and
a radio-frequency (RF) power supply programmed to provide power to a plasma in the processing region during the deposition process, wherein the RF power that is greater than 3000 W; and
a charge drain that collects charge from a surface of the semiconductor substrate during the deposition process and provides a conductive pathway from the processing region for the charge such that the processing region is free of current arcs between the semiconductor substrate and the faceplate during the deposition process.

9. The semiconductor processing chamber of claim 8, wherein the charge drain dissipates charge from the surface of the semiconductor substrate during the deposition process at a rate that is greater than or equal to a rate at which charge forms on the surface of the semiconductor substrate.

10. The semiconductor processing chamber of claim 8, wherein the charge drain comprises a positive electrode in the substrate support, wherein the positive electrode is coupled to a positive output of a bipolar electrostatic chuck (ESC).

11. The semiconductor processing chamber of claim 10, wherein the bipolar ESC comprises a floating power supply with a positive terminal coupled to the positive electrode and a negative terminal that is coupled to a negative electrode in the substrate support.

12. The semiconductor processing chamber of claim 8, wherein the substrate support further comprises a carbon-based layer that allows charge that collects on the substrate support to dissipate through the charge drain.

13. The semiconductor processing chamber of claim 8, wherein the faceplate comprises a conductive surface that dissipates charge that builds up on the faceplate during the deposition process.

14. A semiconductor processing method comprising:
flowing a carbon-containing precursor into a processing region of a semiconductor processing chamber;
forming a plasma of a carbon-containing precursor within the processing region of the semiconductor processing chamber;
applying a first radio-frequency (RF) power to the plasma that is less than 3000 W and forming a carbon-based layer on a faceplate of the semiconductor processing chamber;
applying a second RF power to the plasma that is greater than 3000 W; and
performing a deposition process on a semiconductor substrate disposed within the processing region of the semiconductor processing chamber to form a carbon hardmask film on the semiconductor substrate, wherein the carbon-based layer provides a conductive surface on the faceplate to distribute charge and prevent current arcs between the semiconductor substrate and the faceplate.

15. The semiconductor processing method of claim 14, further comprising, prior to applying the first RF power to the plasma, applying an RF power to the plasma that is less than 1000 W to form an initial layer for the carbon-based layer on a surface of the faceplate.

16. The semiconductor processing method of claim 15, wherein the RF power that is less than 1000 W is applied for between about 20 seconds and about 60 seconds.

17. The semiconductor processing method of claim 14, wherein the first RF power is applied for between about 20 seconds and about 60 seconds.

18. The semiconductor processing method of claim 14, wherein the first RF power is between about 2300 W and about 2500 W.

19. The semiconductor processing method of claim 14, wherein the carbon-based layer is between about 100 nm and about 250 nm thick.

20. The semiconductor processing method of claim 14, further comprising:
draining charge that collects on a surface of the semiconductor substrate during the deposition process through a charge drain that provides a conductive pathway from the processing region.
